(19) United States
(12) Patent Application Publication
(10) Pub. No.: US 2020/0279610 A1
(43) Pub. Date: Sep. 3, 2020

(54) Method for Retaining Data

(71) Applicants: Goke Taiwan Research Laboratory Ltd., Taipei City 114 (TW); Xinsheng Intelligent Technology Co., Ltd., JIANGSU (CN)

(72) Inventors: Po-Chien Chang, Taipei City (TW); Yun-Chang Wang, Zhubei City (TW)

(21) Appl. No.: 16/289,794

(22) Filed: Mar. 1, 2019

(51) Int. Cl. G11C 16/34; G11C 29/50; G11C 11/406; G06F 12/02

(52) U.S. Cl. CPC G11C 16/349; G11C 29/50016; G11C 2211/4061; G06F 12/0246; G11C 11/40603

(57) ABSTRACT

A method is devise for retaining data. In the method, threshold voltage and a corresponding retention time limit are read from a current block. Then, retention time is calculated. Then, it is determined whether the retention time is longer than the retention time limit. A swapping routine is executed if the retention time is longer than the retention time limit. The process returns to the step of calculating the retention time if the retention time is no longer than the retention time limit.

### BACKGROUND OF INVENTION

### 1. Field of Invention

The present invention relates to storage of data and, more particularly, to a method for retaining data.

### 2. Related Prior Art

As technology advances, processes for manufacturing chips progress; however, certain problems get worse. For example, data storage apparatus in a NAND flash memory gets shorter, and a NAND flash memory keeps on losing data even when it is turned off.

Referring to FIG. 1, threshold voltage is distributed as shown in solid lines when data is just stored in a block of a NAND flash memory. The threshold voltage distribution keeps on moving to the left as shown in dash lines as time passes. At least some of the data will be lost after the threshold voltage distribution moves to the left to a certain extent.

To solve the problem with data storage apparatus, a typical method is to read all the pages of all the blocks once every hour for example. Then, it is determined whether the data should be revived based on the amount of bit errors. However, it takes a very long period of time to complete this process.

Referring to FIG. 4, a conventional method for retaining data is shown. At S70, the process begins and reset N to be zero. Then, at S72, it is determined whether an hour has elapsed. The process goes to S74 if so, and goes to S70 if otherwise. At S74, an N^{th} block (“old block”) is read. Then, at S76, it is determined whether the error-correcting code of the old block reaches a threshold. The process goes to S78 if so, and goes to S80 if otherwise. At S78, another block (“new block”) is selected from a pool. Then, at S82, the data is moved to the new block from the old block. Then, at S84, the old block is sent into the pool. At S80, N is added by 1 before the process goes to S74. Then, at S86, it is determined whether N is larger than or equal to a count (or “total number”) of the blocks. The process goes to S88 if so, and returns to S74 if otherwise. At S88, the process ends.

There is however at least one serious problem with this conventional method for retaining data. This conventional method cannot be executed when the NAND flash memory is not turned on. The NAND flash memory will lose at least some of the data if an off period of the NAND flash memory exceeds data storage apparatus, and such loss of data will not be found until a next time the NAND flash memory is turned on. Moreover, some hosts put NAND flash memories into a sleep mode, and there is no time for executing this conventional method.

The present invention is therefore intended to obviate or at least alleviate the problems encountered in prior art.

### SUMMARY OF INVENTION

It is the primary objective of the present invention to provide a reliable method for retaining data.

To achieve the foregoing objective, the method includes the step of reading threshold voltage and a corresponding retention time limit from a current block. Then, retention time is calculated. Then, it is determined whether the retention time is longer than the retention time limit. A swapping routine is executed if the retention time is longer than the retention time limit. The process returns to the step of calculating the retention time if the retention time is no longer than the retention time limit.

Other objectives, advantages and features of the present invention will be apparent from the following description referring to the attached drawings.

### BRIEF DESCRIPTION OF DRAWINGS

The present invention will be described via detailed illustration of the preferred embodiment versus the prior art referring to the drawings wherein:

FIG. 1 shows threshold voltage distribution;

FIG. 2 is a flow chart of a method for predicting a retention time limit according to the preferred embodiment of the present invention;

FIG. 3 is a flow chart of a method for retaining data according to the preferred embodiment of the present invention; and

FIG. 4 is a flow chart of a conventional method for retaining data.

### DETAILED DESCRIPTION OF PREFERRED EMBODIMENT

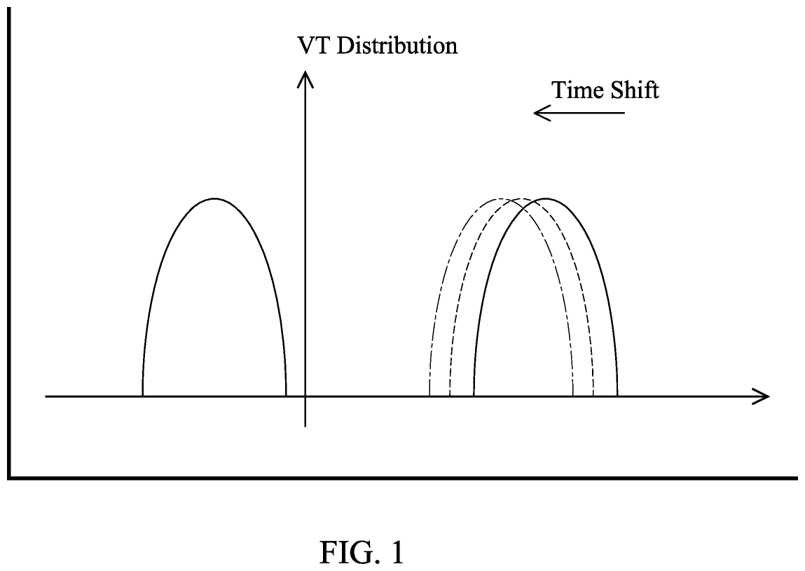

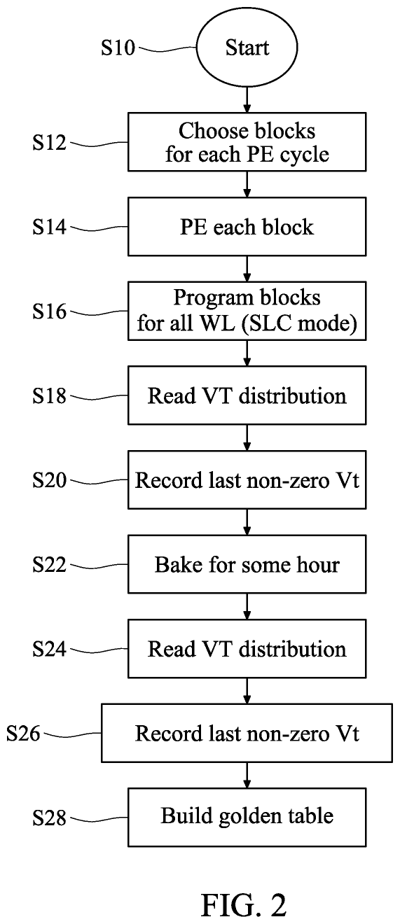

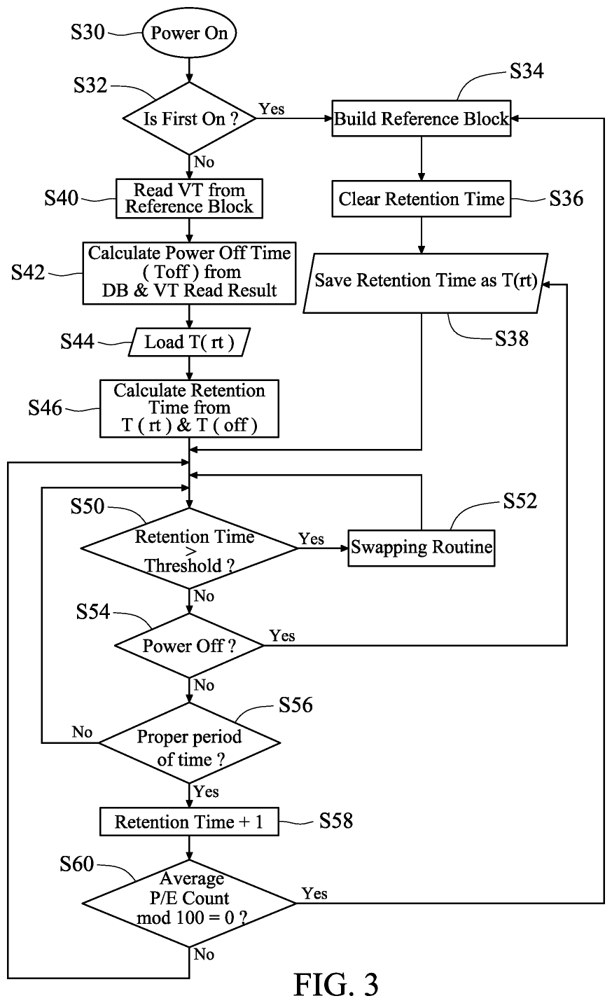

Referring to FIGS. 1 and 2, there is shown a method for predicting a retention time limit according to the preferred embodiment of the present invention. Simulation is used to predict a retention time limit according to the present method. A database is obtained by executing the present method. The database can be used in a method for retaining data according to the preferred embodiment of the present invention to be described referring to FIG. 3.

At S10, the process begins.

At S12, several groups of blocks are selected. For example, five (5) groups of blocks are selected.

Then, at S14, each block of the first group is programmed and erased for 100 times, so that the program/erase count (“PEC”) becomes 100. Each block of the second group is programmed and erased for 200 times, so that the PEC becomes 200. Each block of the third group is programmed and erased for 300 times, so that the PEC becomes 300. Each block of the fourth group is programmed and erased for 400 times, so that the PEC becomes 400. Each block of the fifth group is programmed and erased for 500 times, so that the PEC becomes 500.

Then, at S16, data is written in each page of each block of each group in the form of a single-level cell (“SLC”).

Then, at S18, the threshold voltage distribution of each block is read.

Then, at S20, a last non-zero threshold voltage is recorded.

Then, at S22, the NAND flash memory is baked for a period of time such as several hours. The baking is executed to simulate the elapse of a longer period of time. The baking can however be omitted in another embodiment.

Then, at S24, the threshold voltage distribution of each block of each group is read.

Then, at S26, a last non-zero threshold voltage is recorded.

Then, at S28, a database is built. In specific, at first, a value of drifting is calculated by subtracting the non-zero threshold voltage obtained at S26 from the non-zero threshold voltage obtained at the S20. A table of the values of drifting and the corresponding periods of time is made. Secondly, a drifting rate is calculated by dividing each value of drifting by the corresponding period of time. The drifting rate is an average, and the drifting is actually non-linear. The drifting rates or the table can be used to calculate a period of time (“retention time”) in which the threshold voltage distribution of each block moves to the left.

Referring to FIG. 3, there is shown a method for retaining data according to the preferred embodiment of the present invention. At S30, the NAND flash memory is turned on.

Then, at S32, it is determined whether this is the first time the NAND flash memory is turned on. The process goes to S34 if so, and goes to S40 if otherwise.

At S34, a reference block is selected from the blocks of the NAND flash memory. Only one block is selected. Another block will not be selected until the average PEC reaches a next level. For example, a block is selected when the PEC is 0 in the beginning, and another block is selected only when the PEC reaches 100, and so on. It should be noted that data is written in the reference block in the form of SLC even if data is written in another block in the form of a multiple-level cell (“MLC”).

At S36, retention time Tᵣₜ is cleared from a retention timer of a volatile memory such as a random access memory (“RAM”). The unit of the retention time Tᵣₜ is “minute” for example, and the value of the retention time Tᵣₜ is an integer. Hence, the retention timer is actually a counter that adds 1 to the value of the retention time for every elapsed minute. The first time a user turns on the NAND flash memory apparatus, the retention time Tᵣₜ might not be zero. Hence, the retention time Tᵣₜ must be cleared.

Then, at S38, the value of the retention timer and a reference threshold voltage are stored in a non-volatile memory as the retention time Tᵣₜ. Then, the process goes to S50.

At S40, a threshold voltage is read from the reference block.

Then, at S42, the threshold voltage of the reference block and the data in the database are used to calculate power-off time T_{off}. Power-off time T_{off} is measured from the last time the data storage apparatus was turned off.

Then, at S44, the retention time Tᵣₜ is read. This retention time Tᵣₜ is the retention time Tᵣₜ stored in the non-volatile memory the last time the data storage apparatus was turned off.

Then, at S46, new retention time Tᵣₜ is calculated. This new retention time Tᵣₜ is equal to the retention time Tᵣₜ stored in the non-volatile memory the last time the data storage apparatus was turned off plus the power-off time T_{off}.

Then, at S50, it is determined whether the retention time Tᵣₜ is longer than data storage apparatus. Data storage apparatus is predicted according to the above-mentioned method for predicting a retention time limit according to the preferred embodiment of the present invention. Data storage apparatus is predicted based on the PEC and the threshold voltage of the corresponding block. The process goes to S52 if so, and goes to S54 if otherwise.

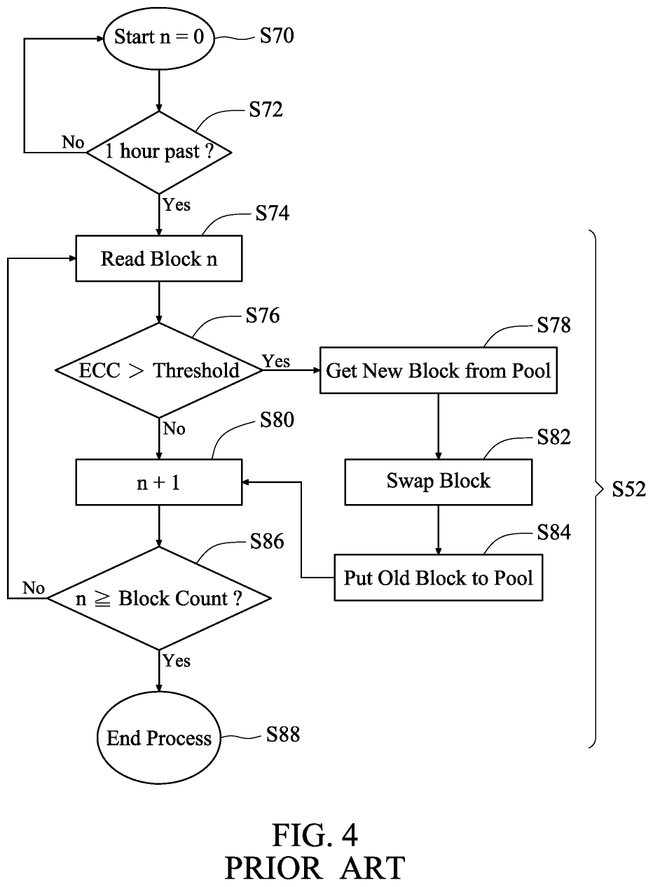

At S52, a swapping routine is executed. The swapping routine includes the steps represented by S74, S76, S78, S80, S82, S84, S86 and S88 referring to FIG. 4. The swapping routine will be described in detail here since it has been discussed in the RELATED PRIOR ART. However, it should be noted that the execution of the swapping routine does not mean swapping actually occurs. Swapping does not occur if the ECC is not large enough.

At S54, it is determined whether the data storage apparatus is to be turned off. The process goes to S38 if so, and goes to S56 if otherwise.

At S56, it is determined whether a proper period of time such as one (1) minute has elapsed. The process goes to S58 if so, and returns to S50 if otherwise.

At S58, the retention time Tᵣₜ is increased by one (1).

Then, at S60, the PEC is divided by a proper number such as 100, and it is determined whether a remainder is zero. The process goes to S34 if so, and returns to S50 if otherwise.

The present invention exhibits several advantages. Firstly, the check is effective and efficient. Secondly, the system immediately predicts when the retention time Tᵣₜ would exceed the retention time limit, and determines whether to swap after the data storage apparatus is turned on. Thirdly, the system immediately detects that the retention time Tᵣₜ has exceeded the retention time limit and take proper actions after the data storage apparatus is turned on. Therefore, the present invention retains data better than the prior art.

The present invention has been described via the illustration of the preferred embodiment. Those skilled in the art can derive variations from the preferred embodiment without departing from the scope of the present invention. Therefore, the preferred embodiment shall not limit the scope of the present invention defined in the claims.

1. A method for predicting a retention time limit comprising the steps of:
turning on a data storage apparatus (S10);
selecting several groups of blocks from the data storage apparatus (S12);
programming and erasing each block of each group a number of times so that the blocks of different groups are programmed and erased different numbers of times (S14);
storing data in each block of each group in the form of a single-level cell (SLC) (S16);
reading threshold voltage distribution from each block of each group (S18);
recording a last non-zero threshold voltage of each block of each group (S20);
keeping the data storage apparatus idle for a proper period of time (S22);
reading the threshold voltage distribution of each block of each group (S24);
recording the last non-zero threshold voltage of each block of each group (S26); and
calculating a retention time limit at which the left-bounding drift of the threshold voltage distribution of each block of each group exceeds a proper threshold.

2. The method according to claim 1, wherein the step of selecting a number of groups of blocks from the data storage apparatus (S12) comprises the step of selecting five (5) groups of blocks from the data storage apparatus.

3. The method according to claim 2, wherein the step (S14) of programming and erasing each block of each group comprises the steps of:
programming and erasing each block of the first group one hundred (100) times;
programming and erasing each block of the second group two hundred (200) times;
programming and erasing each block of the third group three hundred (300) times;
programming and erasing each block of the fourth group four hundred (400) times; and
programming and erasing each block of the fifth group five hundred (500) times.

4. The method according to claim 1, wherein the step (S22) of keeping the data storage apparatus idle for a proper period of time comprises the step of baking the data storage apparatus for a shorter period of time to simulate keeping the data storage apparatus idle for the proper period of time.

5. A method for retaining data comprising the steps of:
reading threshold voltage and a corresponding retention time limit from a current block (S40);
calculating retention time (S46);
determining whether the retention time is longer than the retention time limit (S50);
executing a swapping routine (S52) if the retention time is longer than the retention time limit; and
returning to the step of calculating the retention time (S46) if the retention time is no longer than the retention time limit.

6. The method according to claim 5, wherein the step of calculating the retention time (S46) further comprises the steps of:
calculating power-off time (S42);
reading previous retention time that was recorded the last time the data storage apparatus was turned off (S44); and
calculating the retention time by adding the previous retention time and the power-off time (S46).

7. The method according to claim 6, before returning to the step of calculating the retention time, comprising the steps of:
determining whether the data storage apparatus is to be turned off (S54);
storing the retention time (S38) and a reference threshold voltage if the data storage apparatus is to be turned off;
determining whether a period of time has elapsed if the data storage apparatus is not to be turned off (56);
updating the retention time if the period of time has elapsed; and
returning to the step of determining whether the retention time is longer than the retention time limit if the period of time has not elapsed.

8. The method according to claim 7, wherein the period of time is one (1) minute.

9. The method according to claim 5, wherein the swapping routine comprises the steps of:
determining whether an error-correcting code of the current block is larger than a threshold (S76);
moving data from the current block to another block (S78, S82, S84) and determining whether the current block is a last block (S86) if the error-correcting code of the current block is larger than the threshold;
determining whether the current block is a last block (S86) if the error-correcting code of the current block is not larger than the threshold;
ending the swapping routine if the current block is a last block (S88); and
selecting a new block (S80) and returning to the step of determining whether the error-correcting code of the current block is larger than the threshold (S74) if otherwise.
